(19) United States
(12) Patent Application Publication
(10) Pub. No.: US 2012/0032751 A1
(43) Pub. Date: Feb. 9, 2012

(54) VARIABLE IMPEDANCE MATCHING CIRCUIT

(75) Inventors: Atsushi Fukuda, Yokosuka-shi (JP); Hiroshi Okazaki, Zushi-shi (JP); Shoichi Narahashi, Yokohama-shi (JP)

(73) Assignee: NTT DOCOMO, INC., Chiyoda-ku (JP)

(21) Appl. No.: 13/198,991

(22) Filed: Aug. 5, 2011

(30) Foreign Application Priority Data
Aug. 9, 2010 (JP) 2010-178898

(51) Int. Cl. H03H 7/38

(52) U.S. Cl. 333/32

(57) ABSTRACT

A variable impedance matching circuit includes a series or parallel connection of a fixed inductive element and a first variable capacitive element and a second variable capacitive element connected in series with the serial or parallel connection. The susceptance of the circuit can be changed by changing the capacitances of the variable capacitive elements.

### TECHNICAL FIELD

The present invention relates to a variable impedance matching circuit used with a device such as an amplifier.

### BACKGROUND ART

A power amplifier efficiently amplifies the power of a transmission signal to a power level required by a system. Generally, a radio frequency circuit containing a power amplifier is designed so as to match a certain load (impedance Z₀). However, a load impedance of a power amplifier especially in a mobile terminal varies according to changes of the electromagnetic environment around the antenna and therefore the output power and efficiency of the amplifier can decrease. There is an art in which a tuner is connected between a power amplifier and an antenna in order to reduce degradation due to variations in load. The tuner is made up of variable devices (variable inductive and capacitive elements). The simplest tuner circuit configurations may be combinations of three elements illustrated in FIGS. 14A to 14D. Mathematically, the circuit configurations can deal with any variations in load.

### SUMMARY OF THE INVENTION

A sufficiently wide variable range is demanded of a variable device in order to deal with load variations in a sufficiently wide range. However, while a variable inductive element is mathematically conceivable, no practical inductive element has been commercialized as of this writing. In practice, it is difficult to configure the circuits illustrated in FIGS. 14A to 14D. Therefore, it has needed to take some measures to deal with load variations in a sufficiently wide range, such as increasing the number of elements used.

An object of the present invention is to provide a variable impedance matching circuit capable of adjusting impedance without using a variable inductive element as if the circuit were using a variable inductive element and accordingly capable of dealing with variations in load in a wide range with a small number of elements.

A variable impedance matching circuit of the present invention includes a series or parallel connection of a fixed inductive element and a first variable capacitive element and a second variable capacitive element connected in series with the series or parallel connection, wherein the susceptance of the circuit can be changed by changing the capacitance of each of the variable capacitive elements.

### EFFECTS OF THE INVENTION

The variable impedance matching circuit of the present invention is capable of adjusting impedance without using a variable inductive element as if the circuit were using a variable inductive element. Therefore, the variable impedance matching circuit can deal with load variations in a wide range with a small number of elements.

### BRIEF DESCRIPTION OF THE DRAWINGS

FIG. 1 is a diagram illustrating an exemplary configuration of a variable impedance matching circuit 100 of the present invention;

FIG. 2 is a diagram illustrating an exemplary configuration of the variable impedance matching circuit 100 of the present invention combined with a fixed capacitive element;

FIG. 3 is a diagram illustrating variable capacitance value versus absolute susceptance value characteristics in the variable impedance matching circuit 100 of the present invention;

FIG. 4 is a diagram illustrating an exemplary configuration of a variable impedance matching circuit based on the configuration in FIG. 1 capable of supporting two frequency bands;

FIG. 5 is a diagram illustrating an exemplary configuration of a variable impedance matching circuit based on the configuration in FIG. 2 capable of supporting two frequency bands;

FIG. 6 is a diagram illustrating variable capacitance value versus absolute susceptance value characteristics at an input signal frequency of 2 GHz when a switch in the variable impedance matching circuit in FIG. 4 is turned to an Lₚ₁ₒ_{_{—}}₁ side;

FIG. 7 is a diagram illustrating variable capacitance value versus absolute susceptance value characteristics at an input signal frequency of 2 GHz when a switch in the variable impedance matching circuit in FIG. 4 is turned to an Lₚ₁ₒ_{_{—}}₂ side;

FIG. 8 is a diagram illustrating an exemplary configuration of a variable impedance matching circuit 200 of the present invention;

FIG. 9 is a diagram illustrating an exemplary configuration of the variable impedance matching circuit 200 of the present invention combined with a fixed capacitive element;

FIG. 10 is a diagram illustrating variable capacitance value versus absolute susceptance value characteristics in the variable impedance matching circuit 200 of the present invention;

FIG. 11 is a diagram illustrating an exemplary configuration of a variable impedance matching circuit 300 of the present invention;

FIG. 12 is a diagram illustrating an exemplary configuration of the variable impedance matching circuit 300 of the present invention combined with a fixed capacitive element;

FIG. 13 is a diagram illustrating variable capacitance value versus reactance value characteristics in the variable impedance matching circuit 300 of the present invention;

FIG. 14A is a diagram illustrating a first exemplary configuration of a background-art variable impedance matching circuit;

FIG. 14B is a diagram illustrating a second exemplary configuration of a background-art variable impedance matching circuit;

FIG. 14C is a diagram illustrating a third exemplary configuration of a background-art variable impedance matching circuit; and

FIG. 14D is a diagram illustrating a fourth exemplary configuration of a background-art variable impedance matching circuit.

### DETAILED DESCRIPTION OF THE EMBODIMENTS

Embodiments of the present invention will be described below in detail.

### First Embodiment

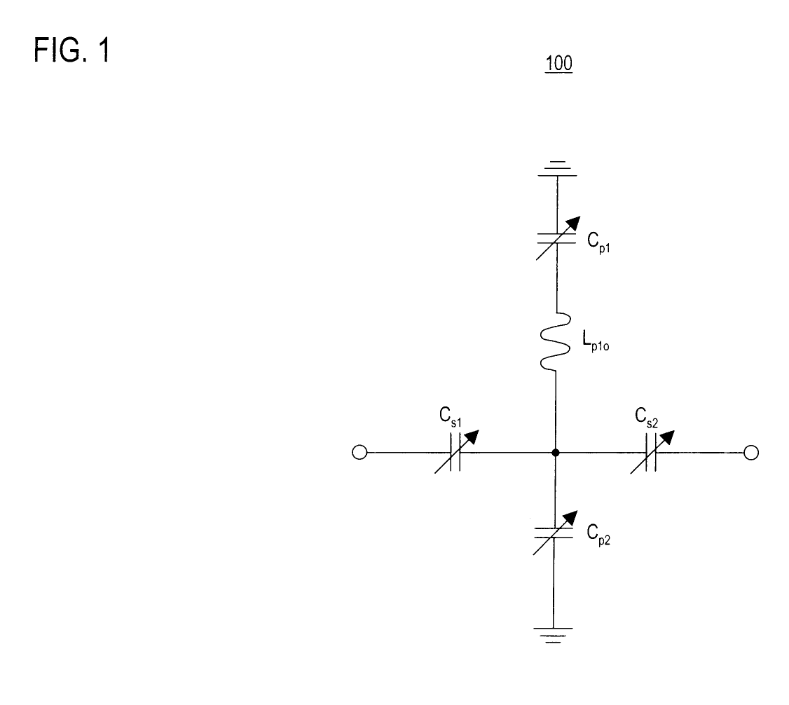

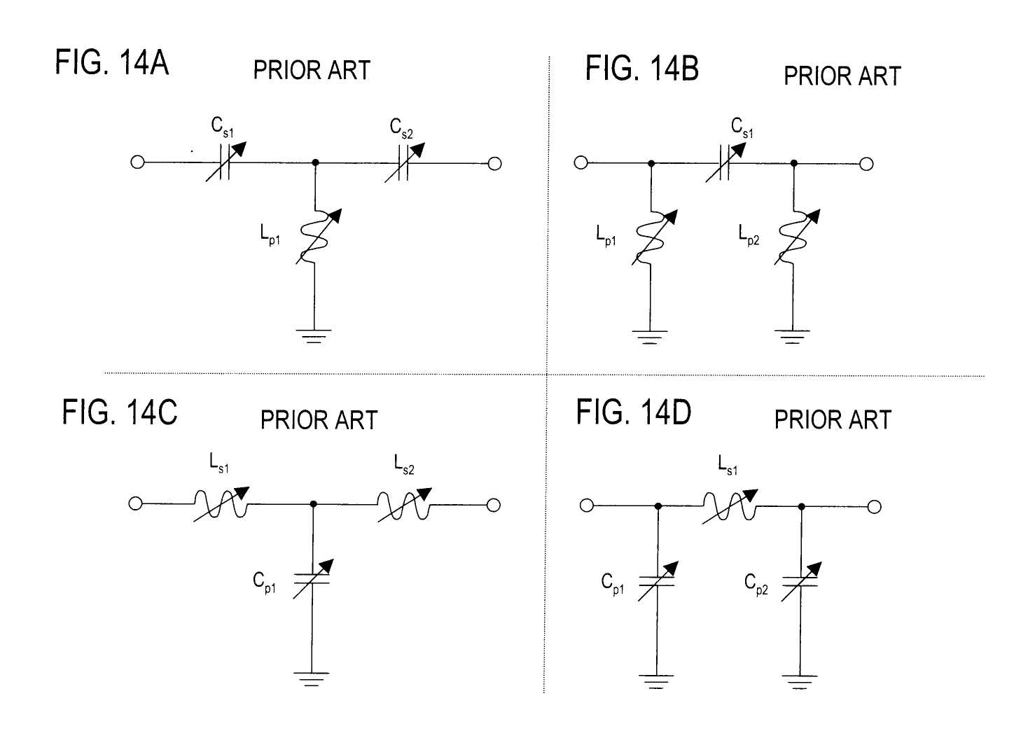

FIG. 1 illustrates an exemplary configuration of a variable impedance matching circuit 100 of the present invention. In the variable impedance matching circuit 100, one fixed inductive element and two variable capacitive elements together act as the variable inductive element Lₚ₁ of the variable circuit in FIG. 14A.

The variable impedance matching circuit 100 includes a series connection of a variable capacitive elements Cₛ₁ and Cₛ₂, and a series connection between a series connection of a fixed inductive element Lₚ₁ₒ and a variable capacitive element Cₚ₁ and a variable capacitive element Cₚ₂. Both ends of the series connection between the series connection of the fixed inductive element Lₚ₁ₒ and the variable capacitive element Cₚ₁ and the variable capacitive element Cₚ₂ are grounded. The connection point of the series connection of the variable capacitive elements Cₛ₁ and Cₛ₂ is connected to the connection point of the series connection between the series connection of the fixed inductive element Lₚ₁ₒ and the variable capacitive element Cₚ₁ and the variable capacitive element Cₚ₂.

The fixed inductive element Lₚ₁ₒ is a fixed inductor having an inductance of Lₚ₁ₒ. The variable capacitive elements Cₚ₁ and Cₚ₂ are variable capacitive elements having capacitances Cₚ₁ and Cₚ₂, respectively. The variable capacitive elements may be implemented by semiconductor elements or implemented using MEMS technology, and may be manufactured and configured by any methods.

The admittance Yₚ₁ of the series connection of the fixed inductive element Lₚ₁ₒ and the variable capacitive element Cₚ₁ is given by the following expression:

$${Y}_{p 1} = \frac{j ω {C}_{p 1}}{1 - {ω}^{2} {L}_{p 1 o} {C}_{p 1}} \qquad ( 1 )$$

where ω is the angular frequency of an input signal.

The admittance Yₚ₂ of the variable capacitive element Cₚ₂ is given by the following expression:

Yₚ₂=jωCₚ₂ (2)

Therefore, the combined admittance Yₚ of Yₚ₁ and Yₚ₂ is as given below:

$${Y}_{p} = \frac{j ω {C}_{p 1}}{1 - {ω}^{2} {L}_{p 1 o} {C}_{p 1}} + j ω {C}_{p 2} \qquad ( 3 )$$

Therefore, Yₚ is inductive admittance when the following relational expression holds:

−∞<Yₚ≦0 (4)

Here, from Expressions (3) and (4), the following expressions can be obtained.

$$\begin{matrix}1 - {ω}^{2} {L}_{p 1 o} {C}_{p 1} \leq 0 & ( 5 a ) \\ - ∞ < \frac{j ω {C}_{p 1}}{1 - {ω}^{2} {L}_{p 1 o} {C}_{p 1}} + j ω {C}_{p 2} \leq 0 & ( 5 b )\end{matrix}$$

Furthermore, from Expressions (5a) and (5b) the following expressions can be obtained.

$$\begin{matrix}{C}_{p 1} \geq \frac{1}{{ω}^{2} {L}_{p 1 o}} & ( 6 a ) \\ {C}_{p 2} \leq \frac{{C}_{p 1}}{{ω}^{2} {L}_{p 1 o} {C}_{p 1} - 1} & ( 6 b )\end{matrix}$$

Differentiating the right-hand side of Expression (6b) in Cₚ₁ yields the following expression.

$$\frac{1}{{dC}_{p 1}} \{ \frac{{C}_{p 1}}{{ω}^{2} {L}_{p 1 o} {C}_{p 1} - 1} \} = \frac{- 1}{{( {ω}^{2} {L}_{p 1 o} {C}_{p 1} - 1 )}^{2}} < 0 \qquad ( 7 )$$

Because the right-hand side of Expression (6b) monotonically decreases with respect to Cₚ₁, the maximum value Cₚ₂ₘₐₓ of Cₚ₂ is a minimum when Cₚ₁ is its maximum value Cₚ₁ₘₐₓ. Therefore, the required ranges of Cₚ₁ and Cₚ₂ are:

$$\begin{matrix}0 \leq {C}_{p 1 min} \leq \frac{1}{{ω}^{2} {L}_{p 1 o}} and \frac{1}{{ω}^{2} {L}_{p 1 o}} < {C}_{p 1 max} & ( 8 a ) \\ {C}_{p 2 min} < \frac{1}{{ω}^{2} {L}_{p 1 o}} and \frac{1}{{ω}^{2} {L}_{p 1 o}} \leq {C}_{p 2 max} & ( 8 b )\end{matrix}$$

From the foregoing it follows that Yₚ is inductive admittance when Cₚ₁ is in the range of Expression (8a) and Cₚ₂ is in the range of Expression (8b). Therefore, the set of the single fixed inductive element Lₚ₁ₒ and the two variable capacitive elements Cₚ₁ and Cₚ₂ can be caused to function as if the set were a variable inductive element. Thus, the set can act as the variable inductive element Lₚ₁ in the variable matching circuit in FIG. 14A. A normal variable capacitive element has its specific variable capacitance range. Therefore, variable capacitive elements that have the variable capacitance ranges as given below may be used as Cₚ₁ and Cₚ₂:

Cₚ₁ₘᵢₙ≦Cₚ₁≦Cₚ₁ₘᵢₙ+Δₚ₁=Cₚ₁ₘₐₓ (9a)

Cₚ₂ₘᵢₙ=Cₚ₂ₘₐₓ−Δₚ₂≦Cₚ₂≦Cₚ₂ₘₐₓ (9b)

where Δₚ₁ and Δₚ₂ are the variable capacitance ranges.

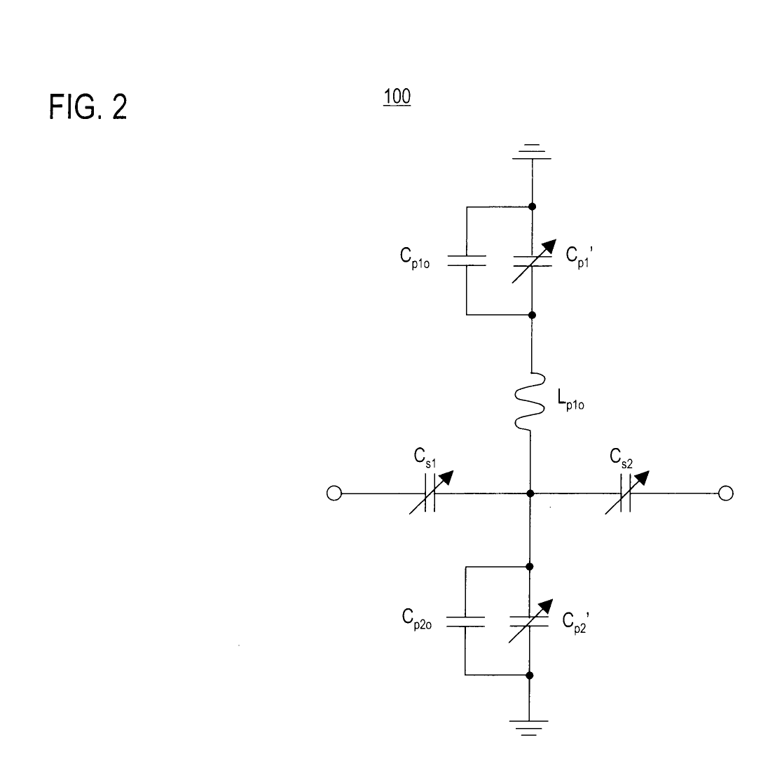

The smaller the absolute value of the capacitance of a variable capacitive element, the smaller the size of the capacitive element. In order to reduce the absolute value of the capacitance, the variable capacitive element Cₚ₁ may be formed by a fixed capacitive element Cₚ₁ₒ (0<Cₚ₁ₒ≦Cₚ₁ₘᵢₙ) and a variable capacitive element Cₚ₁′ provided in parallel with the fixed capacitive element Cₚ₁ₒ and, similarly, the variable capacitive element Cₚ₂ may be formed by a fixed capacitive element Cₚ₂ₒ (0<Cₚ₂ₒ≦Cₚ₂ₘₐₓ−Δₚ₂) and a variable capacitive element Cₚ₂′ provided in parallel with the fixed capacitive element Cₚ₂ₒ as illustrated in FIG. 2. With this configuration, the absolute values of the capacitances of the variable capacitive elements Cₚ₁′ and Cₚ₂′ used can be reduced from the absolute values of the capacitances of Cₚ₁ and Cₚ₂ in Expressions (9a) and (9b) by Cₚ₁ₒ and Cₚ₂ₒ, respectively, as shown by the expressions given below. With this configuration, smaller variable capacitive elements can be used.

Cₚ₁ₘᵢₙ−Cₚ₁ₒ≦Cₚ₁′≦Cₚ₁ₘᵢₙ−Cₚ₁ₒ+Δₚ₁ (10a)

Cₚ₂ₘₐₓ−Δₚ₂−Cₚ₂ₒ≦Cₚ₂′≦Cₚ₂ₘₐₓ−Cₚ₂ₒ (10b)

A variable susceptance range that can be obtained by changing Cₚ₁ and Cₚ₂ when the set of the single fixed inductive element Lₚ₁ₒ and the two variable capacitive elements Cₚ₁ and Cₚ₂ in the configuration in FIG. 1 is caused to function as if the set were a variable inductive element will be calculated. Then, the inductance range equivalent to the variable susceptance range that would be achieved only by an inductor will be determined.

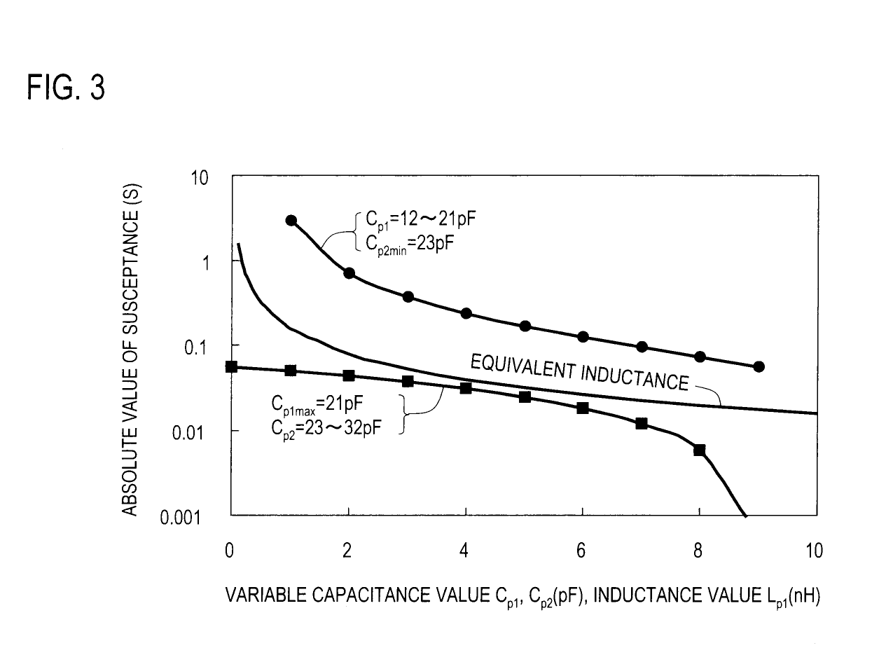

By way of illustration, required Cₚ₁ and Cₚ₂ when an input signal frequency is 1 GHz and Lₚ₁ₒ is 2 nH will be calculated. From Expression (8a), Cₚ₁ₘᵢₙ is approximately 12.7 pF. For simplicity, assume that Cₚ₁ₘᵢₙ is 12 pF and Δₚ₁ is 9 pF. Then 12≦Cₚ₁≦21 pF. Here, since Cₚ₁ₘₐₓ is 21 pF, Cₚ₂ₘₐₓ is 31.9 pF from Expression (8b). For simplicity, assume that Cₚ₂ₘₐₓ is 32 pF and Δₚ₂ is 9 pF. Then 23 Cₚ₂≦32 pF. FIG. 3 illustrates plots of the absolute value of susceptance in the configuration in FIG. 2 in which Cₚ₁ in FIG. 1 is divided into two, Cₚ₁′ and Cₚ₁ₒ, and Cₚ₂ in FIG. 1 is divided into two, Cₚ₂′ and Cₚ₂ₒ, where Cₚ₁ₒ=12 pF, Cₚ₂ₒ=23 pF, and variable capacitance values Cₚ₁′ and Cₚ₂′ are changed in the ranges Δₚ₁ and Δₚ₂ (0 to 9 pF), respectively (variable capacitance value versus absolute susceptance value characteristics). The filled circles represent a plot obtained by changing Cₚ₁′ while Cₚ₂ is fixed at Cₚ₂ₘᵢₙ (=23 pF) and filled squares represent a plot obtained by changing Cₚ₂′ while Cₚ₁ is fixed at Cₚ₁ₘₐₓ (=21 pF). The solid curve without circles nor squares represents the absolute value of susceptance obtained by changing the inductance value equivalent to the variable inductive element Lₚ₁ in FIG. 14A in the range of 0 to 10 nH. It can be seen from FIG. 3 that susceptance value adjustment in a range equivalent to a range achievable by changing the inductance value Lₚ₁ by 10 nH or more can be achieved by changing the values of Cₚ₁ and Cₚ₂, when the input signal frequency=1 GHz, Lₚ₁ₒ=2 nH, Cₚ₁=12 to 21 pF and Cₚ₂=23 to 32 pF.

The configuration in FIG. 14A has been changed to a configuration that does not use a variable inductive element in the first embodiment described above. The configuration in FIG. 14B also can be changed to a configuration that does not use a variable inductive element in a way similar to that in the first embodiment.

In this way, the variable impedance matching circuit 100 of the present invention is capable of adjusting impedance without using a variable inductive element as if the circuit 100 were using a variable inductive element. Accordingly, the variable impedance matching circuit 100 is capable of dealing with variations in load in a wide range with a small number of elements.

[Variation]

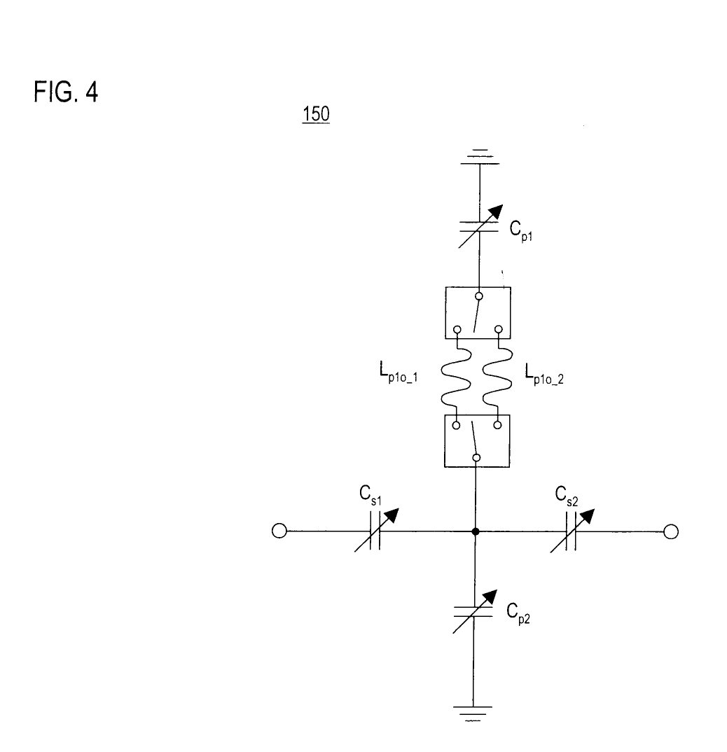

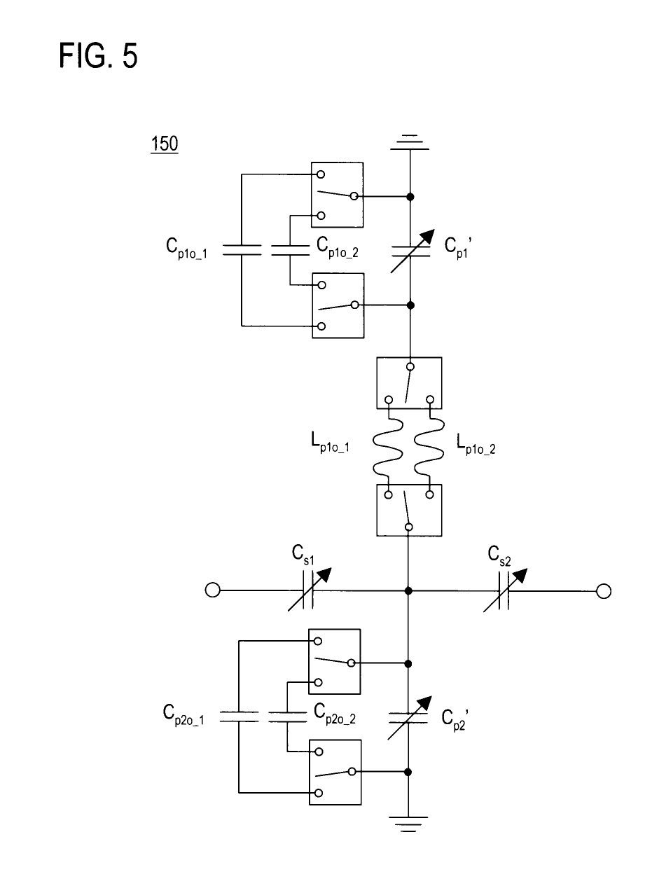

In the variable impedance matching circuit 100 of the present invention, the fixed inductive element Lₚ₁ₒ and the fixed capacitive elements Cₚ₁ₒ and Cₚ₂ₒ are optimized for different frequency bands used and are allowed to be alternately selected by a switch, thereby a variable impedance matching circuit that can be used with multiple frequency bands can be configured. FIGS. 4 and 5 illustrate exemplary configurations of a variable impedance matching circuit 150 based on the configurations in FIGS. 1 and 2, respectively, that can be used with two frequency bands. In the configuration in FIG. 4, fixed inductive elements Lₚ₁ₒ_{_{—}}₁ and Lₚ₁ₒ_{_{—}}₂ can be alternately selected by two SPDT switches according to a frequency band used. In the configuration in FIG. 5, a pair of fixed inductive elements Lₚ₁ₒ_{_{—}}₁ and Lₚ₁ₒ_{_{—}}₂, a pair of fixed capacitive elements Cₚ₁ₒ_{_{—}}₁ and Cₚ₁₀_{_{—}}₂, and a pair of fixed capacitive elements Cₚ₂ₒ_{_{—}}₁ and Cₚ₂ₒ_{_{—}}₂ can be alternately selected by two SPDT switches according to a frequency band used.

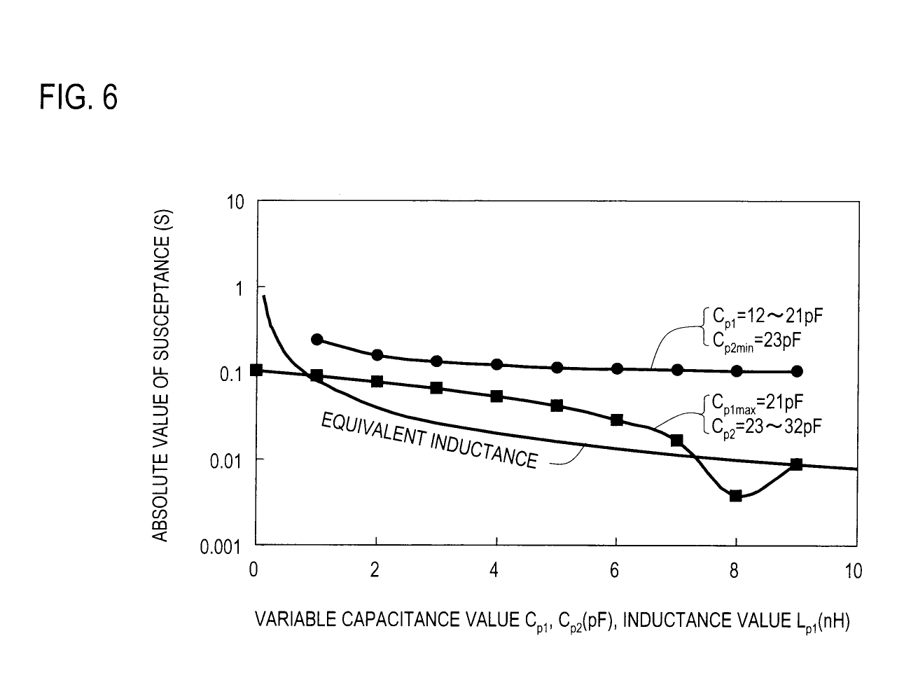

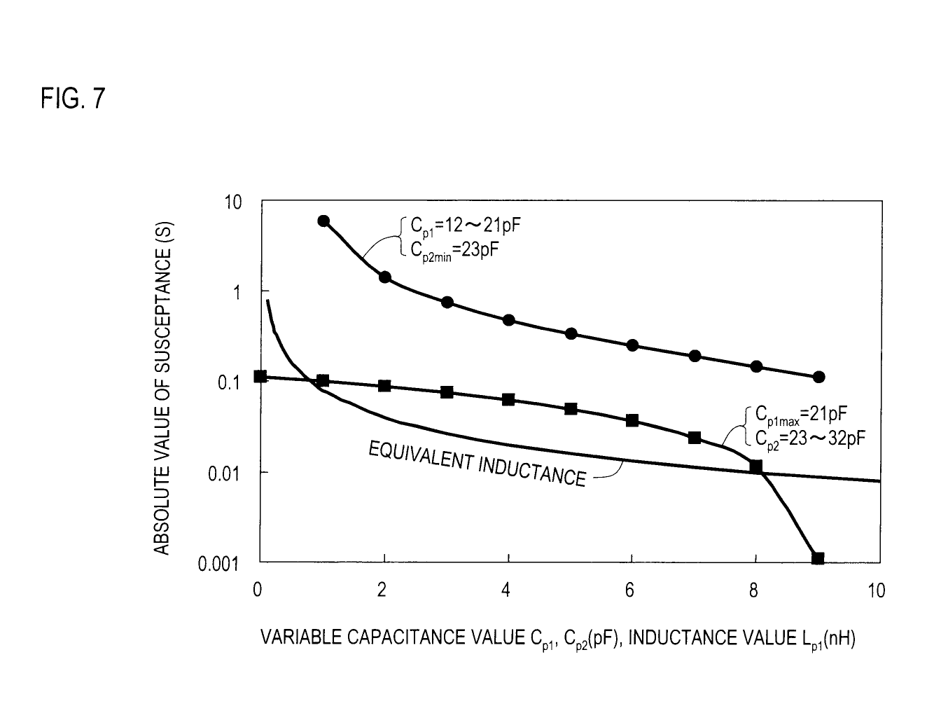

Variable capacitance value versus absolute susceptance value characteristics obtained when the capacitance value of each variable capacitive element in the configuration in FIG. 4 is changed in the same way as in FIG. 3 will be determined. Here, Lₚ₁ₒ_{_{—}}₁ is 2 nH and Lₚ₁ₒ_{_{—}}₂ is 0.5 nH. When the switches are turned to the Lₚ₁ₒ_{_{—}}₁ side, the same configuration as that in FIG. 1 is provided. Accordingly, the variable capacitance value versus susceptance absolute value characteristics as illustrated in FIG. 3 are obtained when a signal of a frequency of 1 GHz is input. When a signal of a frequency of 2 GHz is input, the variable capacitance value versus susceptance absolute value characteristics illustrated in FIG. 6 are obtained. It can be seen from FIG. 6 that the range of the susceptance absolute values covered is narrower than the range covered when the 1-GHz signal is input. FIG. 7 illustrates variable capacitance value versus susceptance absolute value characteristics obtained when the switches are turned to the Lₚ₁ₒ_{_{—}}₂ side to input a signal of a frequency of 2 GHz. It can be seen from FIG. 7 that susceptance absolute values equivalent to the susceptance values obtained with 1 GHz can be obtained with 2 GHz by using Lₚ₁ₒ_{_{—}}₂ optimized for the input signal of 2 GHz.

### Second Embodiment

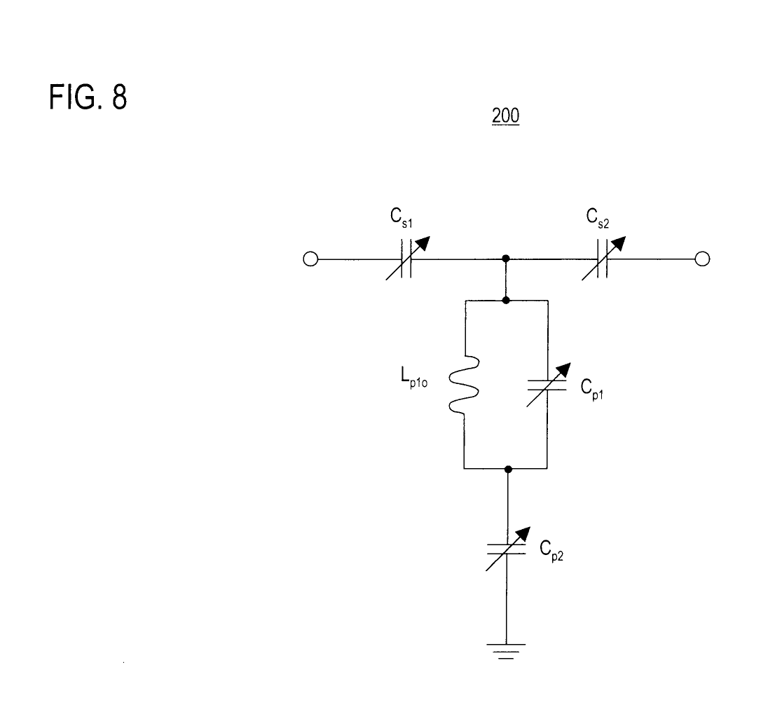

FIG. 8 illustrates an exemplary configuration of a variable impedance matching circuit 200 of the present invention. The variable impedance matching circuit 200 has another configuration in which one fixed inductive element and two variable capacitive elements together act as the variable inductive element Lₚ₁ in the variable matching circuit in FIG. 14A, as in the first embodiment.

The variable impedance matching circuit 200 includes a series connection of a variable capacitive elements Cₛ₁ and Cₛ₂, a series connection between a parallel connection of a fixed inductive element Lₚ₁ₒ and a variable capacitive element Cₚ₁ and a variable capacitive element Cₚ₂. One end of the series connection between the parallel connection of the fixed inductive element Lₚ₁ₒ and the variable capacitive element Cₚ₁ and the variable capacitive element Cₚ₂ is connected to the connection point between the variable capacitive elements Cₛ₁ and Cₛ₂ and the other end is grounded.

The fixed inductive element Lₚ₁ₒ is a fixed inductor with an inductance of Lₚ₁ₒ. The variable capacitive elements Cₚ₁ and Cₚ₂ are variable capacitive elements having capacitances of Cₚ₁ and Cₚ₂, respectively. The variable capacitive elements may be implemented by semiconductor elements or implemented using MEMS technology, and may be manufactured and configured by any methods.

The impedance Zₚ₁ of the parallel connection of the fixed inductive element Lₚ₁ₒ and the variable capacitive element Cₚ₁ can be given by the following expression.

$${Z}_{p 1} = \frac{jω {L}_{p 1 o}}{1 - {ω}^{2} {L}_{p 1 o} {C}_{p 1}} \qquad ( 11 )$$

The impedance Zₚ₂ of the variable capacitive element Cₚ₂ can be given by the following expression.

$${Z}_{p 2} = \frac{1}{jω {C}_{p 2}} \qquad ( 12 )$$

Therefore, the combined impedance Zₚ of Zₚ₁ and Zₚ₂ is as given below.

$${Z}_{p} = \frac{jω {L}_{p 1 o}}{1 - {ω}^{2} {L}_{p 1 o} {C}_{p 1}} + \frac{1}{jω {C}_{p 2}} \qquad ( 13 )$$

Therefore, Zₚ is inductive impedance when the following relational expression holds:

0≦Zₚ<∞ (14)

Here, the following expressions can be obtained from Expressions (13) and (14).

$$\begin{matrix}1 - {ω}^{2} {L}_{p 1 o} {C}_{p 1} \geq 0 & ( 15 a ) \\ 0 \leq \frac{ω {L}_{p 1 o}}{1 - {ω}^{2} {L}_{p 1 o} {C}_{p 1}} - \frac{1}{ω {C}_{p 2}} < ∞ & ( 15 b )\end{matrix}$$

Furthermore, the following expressions can be obtained from Expressions (15a) and (15b).

$$\begin{matrix}{C}_{p 1} \leq \frac{1}{{ω}^{2} {L}_{p 1 o}} & ( 16 a ) \\ {C}_{p 2} \geq \frac{1 - {ω}^{2} {L}_{p 1 o} {C}_{p 1}}{{ω}^{2} L - {L}_{p 1 o}} & ( 16 b )\end{matrix}$$

Here, differentiating the right-hand side of Expression (16b) in Cₚ₁ yields the following expression:

$$\frac{1}{{dC}_{p 1}} \{ \frac{1 - {ω}^{2} {L}_{p 1 o} {C}_{p 1}}{{ω}^{2} {L}_{p 1 o}} \} = - 1 \qquad ( 17 )$$

Because the right-hand side of Expression (16b) monotonically decreases with respect to Cₚ₁, the minimum value Cₚ₂ₘᵢₙ of Cₚ₂ is a maximum when Cₚ₁ is its minimum value Cₚ₁ₘᵢₙ. Therefore, the required ranges of Cₚ₁ and Cₚ₂ are:

$$\begin{matrix}{C}_{p 1 min} < \frac{1}{{ω}^{2} {L}_{p 1 o}} and \frac{1}{{ω}^{2} {L}_{p 1 o}} \leq {C}_{p 1 max} & ( 18 a ) \\ 0 \leq {C}_{p 2 min} \leq \frac{1 - {ω}^{2} {L}_{p 1 o} {C}_{p 1 min}}{{ω}^{2} {L}_{p 1 o}} \\ and \\ \frac{1 - {ω}^{2} {L}_{p 1 o} {C}_{p 1 min}}{{ω}^{2} {L}_{p 1 o}} < {C}_{p 2 max} & ( 18 b )\end{matrix}$$

From the foregoing it follows that Zₚ is inductive impedance when Cₚ₁ is in the range of Expression (18a) and Cₚ₂ is in the range of Expression (18b). Therefore, the set of the single fixed inductive element Lₚ₁ₒ and the two variable capacitive elements Cₚ₁ and Cₚ₂ can be caused to function as if the set were a variable inductive element. Thus, the set can act as the variable inductive element Lₚ₁ in the variable matching circuit in FIG. 14A. A normal variable capacitive element has its specific variable capacitance range. Therefore, variable capacitive elements that have the variable capacitance ranges as given below may be used as Cₚ₁ and Cₚ₂:

Cₚ₁ₘᵢₙ=Cₚ₁ₘₐₓ−Δₚ₁≦Cₚ₁≦Cₚ₁ₘₐₓ (19a)

Cₚ₂ₘᵢₙ≦Cₚ₂≦Cₚ₂ₘᵢₙ+Δₚ₂=Cₚ₂ₘₐₓ (19b)

where Δₚ₁ and Δₚ₂ are the variable capacitance ranges.

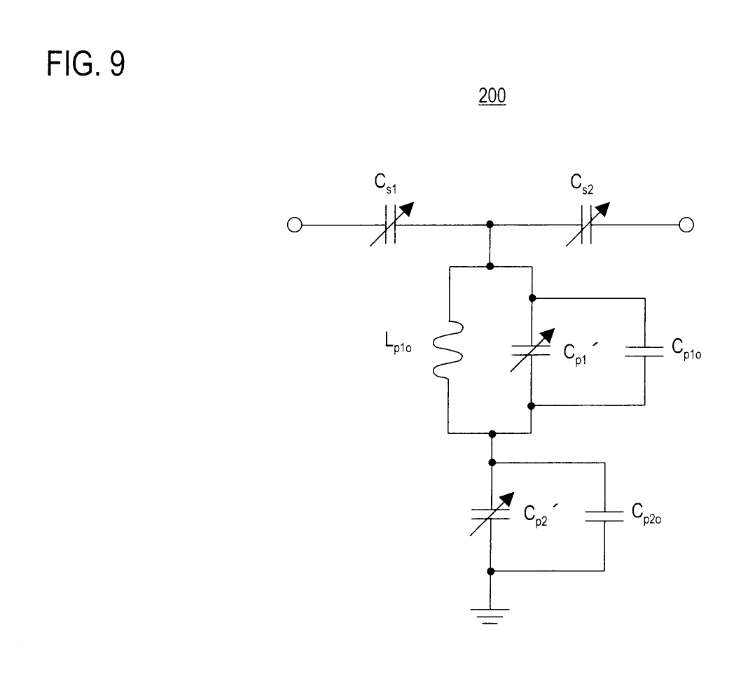

The smaller the absolute value of the capacitance of a variable capacitive element, the smaller the size of the capacitive element. In order to reduce the absolute value of the capacitance, the variable capacitive element Cₚ₁ is formed by a fixed capacitive element Cₚ₁ₒ (0<Cₚ₁ₒ≦Cₚ₁ₘₐₓ−Δₚ₁) and a variable capacitive element Cₚ₁′ provided in parallel with the fixed capacitive element Cₚ₁ₒ as illustrated in FIG. 9. Similarly, the variable capacitive element Cₚ₂ may be formed by a fixed capacitive element Cₚ₂ₒ (0<Cₚ₂ₒ≦Cₚ₂ₘᵢₙ) and a variable capacitive element Cₚ₂′ provided in parallel with the fixed capacitive element Cₚ₂ₒ. With this configuration, the absolute values of the capacitances of the variable capacitive elements Cₚ₁′ and Cₚ₂′ used can be reduced from the absolute values of the capacitances of Cₚ₁ and Cₚ₂ in Equations (19a) and (19b) by Cₚ₁ₒ and Cₚ₂ₒ, respectively, as shown by Expressions given below. Accordingly, smaller variable capacitive elements can be used.

Cₚ₁ₘₐₓ−Cₚ₁ₒ−Δ≦Cₚ₁′≦Cₚ₁ₘₐₓ−Cₚ₁ₒ (20a)

Cₚ₂ₘᵢₙ−Cₚ₂ₒ≦Cₚ₂′≦Cₚ₂ₘᵢₙ+Δₚ₂−Cₚ₂ₒ (20b)

A variable susceptance range that can be obtained by changing Cₚ₁ and Cₚ₂ when the set of the single fixed inductive element Lₚ₁ₒ and the two variable capacitive elements Cₚ₁ and Cₚ₂ in the configuration in FIG. 8 is caused to function as if the set were a variable inductive element will be calculated. Then, the inductance range equivalent to the variable susceptance range that would be achieved only by an inductor will be determined.

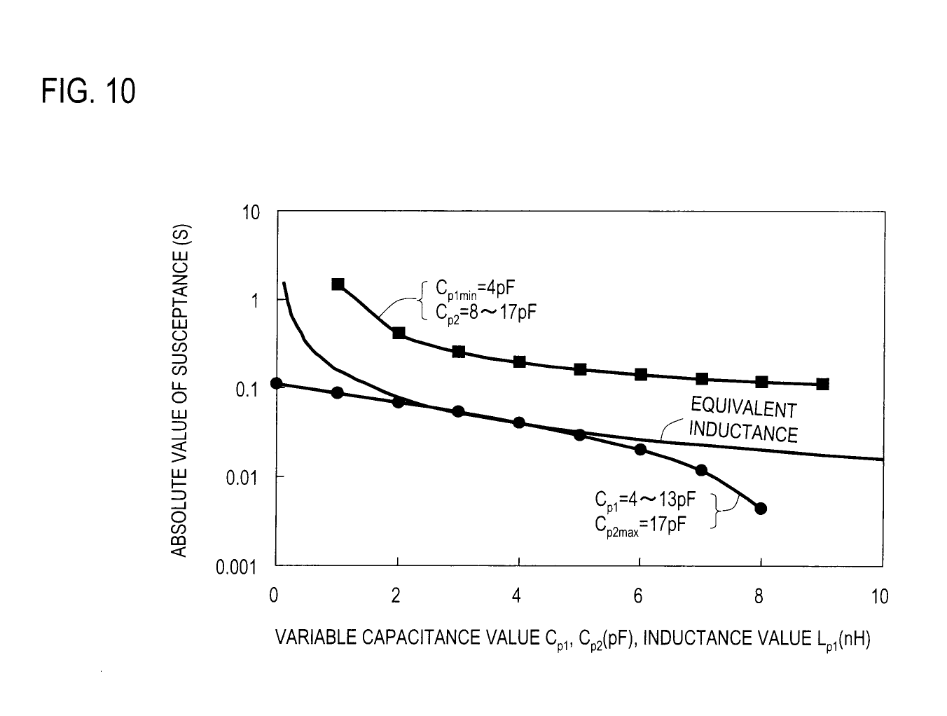

By way of illustration, required Cₚ₁ and Cₚ₂ when an input signal frequency is 1 GHz and Lₚ₁ₒ is 2 nH will be calculated. From Expression (18a), Cₚ₁ₘₐₓ is approximately 12.7 pF. For simplicity, assume that Cₚ₁ₘₐₓ is 13 pF and Δₚ₁ is 9 pF. Then 4≦Cₚ₁≦Cₚ₁≦13 pF. Here, since Cₚ₁ₘᵢₙ is 4 pF, Cₚ₂ₘᵢₙ is 8.7 pF or more from Expression (18b). For simplicity, assume that Cₚ₂ₘₘ is 8 pF and Δₚ₂ is 9 pF. Then 8≦ₚ₂≦17 pF. FIG. 10 illustrates plots of the absolute value of susceptance in the configuration in FIG. 9 in which Cₚ₁ in FIG. 8 is divided into two, Cₚ₁ₒ′ and Cₚ₁ₒ, and Cₚ₂ in FIG. 8 is divided into two, Cₚ₂′ and Cₚ₂ₒ, where Cₚ₁ₒ=4 pF, Cₚ₂ₒ=8 pF, and variable capacitance values Cₚ₁′ and Cₚ₂′ are changed in the ranges Δₚ₁ and Δₚ₂ (0 to 9 pF), respectively (variable capacitance value versus absolute susceptance value characteristics). The filled circles represent a plot obtained by changing Cₚ₁′ while Cₚ₂ is fixed at Cₚ₂ₘₐₓ (=17 pF) and filled squares represent a plot obtained by changing Cₚ₂′ while Cₚ₁ is fixed at Cₚ₁ₘᵢₙ (=4 pF). The solid curve without circles nor squares represents the absolute value of susceptance obtained by changing the inductance value equivalent to the variable inductive element Lₚ₁ in FIG. 14A in the range of 0 to 10 nH. It can be seen from FIG. 10 that susceptance value adjustment in a range equivalent to a range achievable by changing the inductance value Lₚ₁ by 10 nH or more can be achieved by changing the values of Cₚ₁ and Cₚ₂, when the input signal frequency=1 GHz, Lₚ₁ₒ=2 nH, Cₚ₁=4 to 13 pF and Cₚ₂=8 to 17 pF.

The configuration in FIG. 14A has been changed to a configuration that does not use a variable inductive element in the second embodiment described above. The configuration in FIG. 14B also can be changed to a configuration that does not use a variable inductive element in a way similar to that in the second embodiment.

In this way, the variable impedance matching circuit 200 of the present invention is capable of adjusting impedance without using a variable inductive element as if the circuit 200 were using a variable inductive element. Accordingly, the variable impedance matching circuit is capable of dealing with variations in load in a wide range with a small number of elements. If required susceptance values are within a more limited range, Cₚ₂ may be replaced with a fixed capacitance. Furthermore, the configurations of the variation of the first embodiment can be used in the second embodiment to configure a variable impedance matching circuit that can be used with multiple frequency bands.

### Third Embodiment

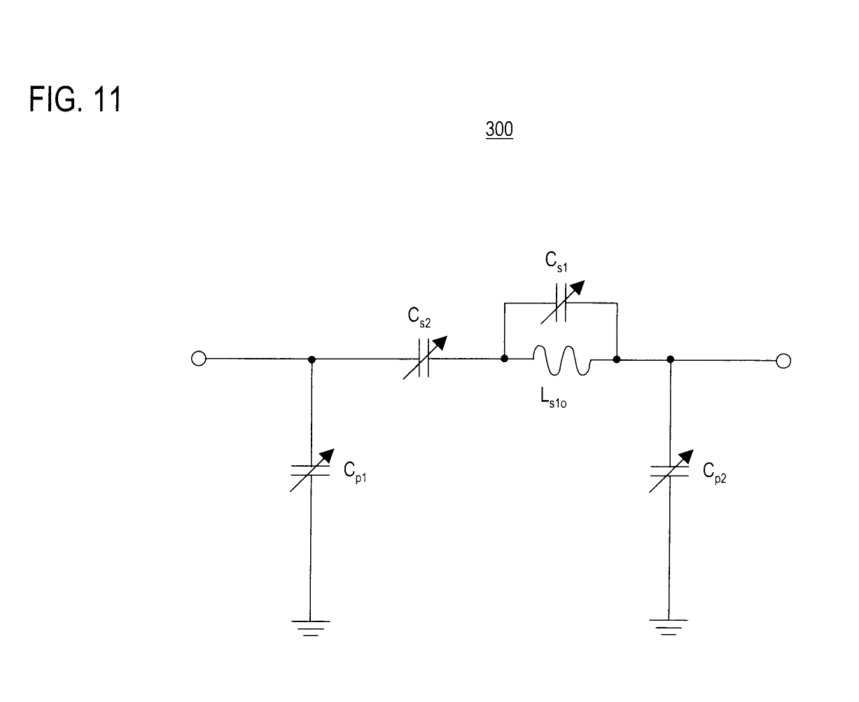

FIG. 11 illustrates an exemplary configuration of a variable impedance matching circuit 300 of the present invention. The variable impedance matching circuit 300 has a configuration in which one fixed inductive element and two variable capacitive elements together act as the variable inductive element Lₛ₁ in the variable matching circuit in FIG. 14D.

The variable impedance matching circuit 300 includes a series connection between a parallel connection of a fixed inductive element Lₛ₁₀ and a variable capacitive element Cₛ₁ and a variable capacitive element Cₛ₂.

The variable impedance matching circuit 300 also includes a variable capacitive element Cₚ₁ one end of which is connected to one end of the series connection and the other end of which is grounded, and a variable capacitive element Cₚ₂ one end of which is connected to the other end of the series connection and the other end of which is grounded.

The fixed inductive element Lₛ₁ₒ is a fixed inductor with an inductance of Lₛ₁ₒ. The variable capacitive elements Cₛ₁ and Cₛ₂ are variable capacitive elements having capacitances of Cₛ₁ and Cₛ₂, respectively. The conditions of the elements are the same as the conditions in the second embodiment, except that the fixed inductive element Lₚ₁ₒ in the second embodiment is replaced with the fixed inductive element Lₛ₁ₒ, the variable capacitive element Cₚ₁ is replaced with the variable capacitive element Cₛ₁ and the variable capacitive element Cₚ₂ is replaced with the variable capacitive element Cₛ₂. Alternatively, the variable capacitive element Cₛ₁ may be formed by a parallel connection of a fixed capacitive element Cₛ₁ₒ and a variable capacitive element Cₛ₁′ having a smaller capacitance and the variable capacitive element Cₛ₂ may be formed by a parallel connection of a fixed capacitive element Cₛ₂ₒ and a variable capacitive element Cₛ₂′ having a smaller capacitance, thereby smaller variable capacitive elements can be used. In this case, the capacitances of the fixed capacitance elements Cₛ₁ₒ and Cₛ₂ₒ and the variable capacitive elements Cₛ₁′ and Cₛ₂′ that correspond to the variable capacitive elements Cₛ₁ and Cₛ₂, respectively, can be calculated by replacing Cₚ₁, Cₚ₂, Cₚ₁ₒ, Cₚ₂ₒ, Cₚ₁′ and Cₚ₂′ with Cₛ₁, Cₛ₂, Cₛ₁ₒ, Cₛ₂ₒ, Cₛ₁′ and Cₛ₂′, respectively, in the method calculating Cₚ₁ₒ, Cₚ₁′ and Cₚ₂ₒ. Cₚ₂′ that correspond to Cₚ₁ and Cₚ₂, respectively, described in the second embodiment.

The variable capacitive elements may be implemented by semiconductor elements or may be implemented using MEMS technology and may be manufactured and configured by any methods.

A variable reactance range that can be obtained by changing Cₛ₁ and Cₛ₂ when the set of the single fixed inductive element Lₛ₁ₒ and the two variable capacitive elements Cₛ₁ and Cₛ₂ in the configuration in FIG. 11 is caused to function as if the set were a variable inductive element will be calculated. Then, the inductance range equivalent to the variable reactance range that would be achieved only by an inductor will be determined.

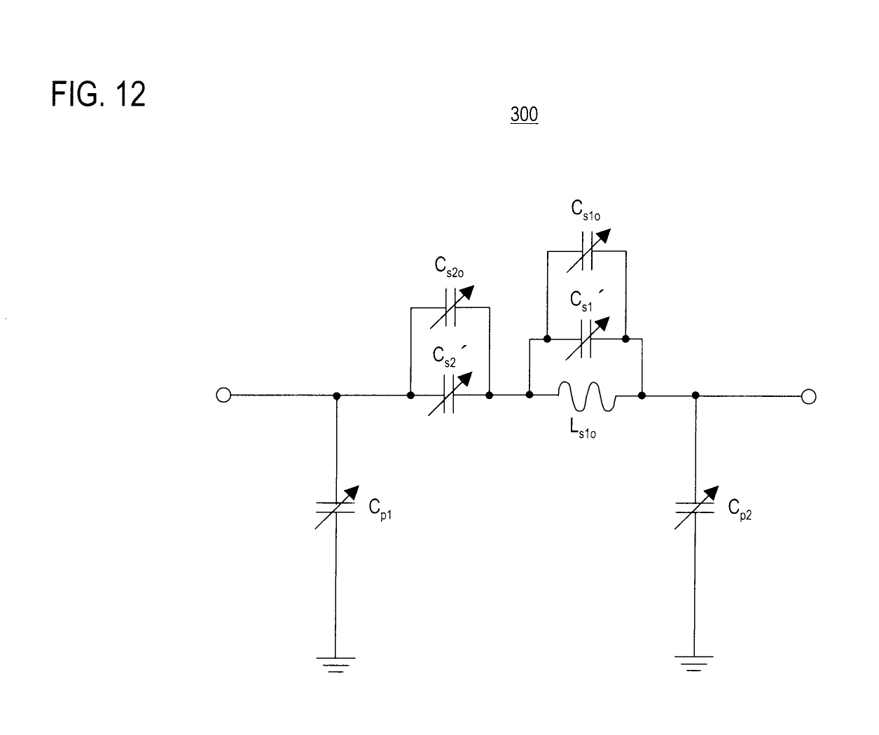

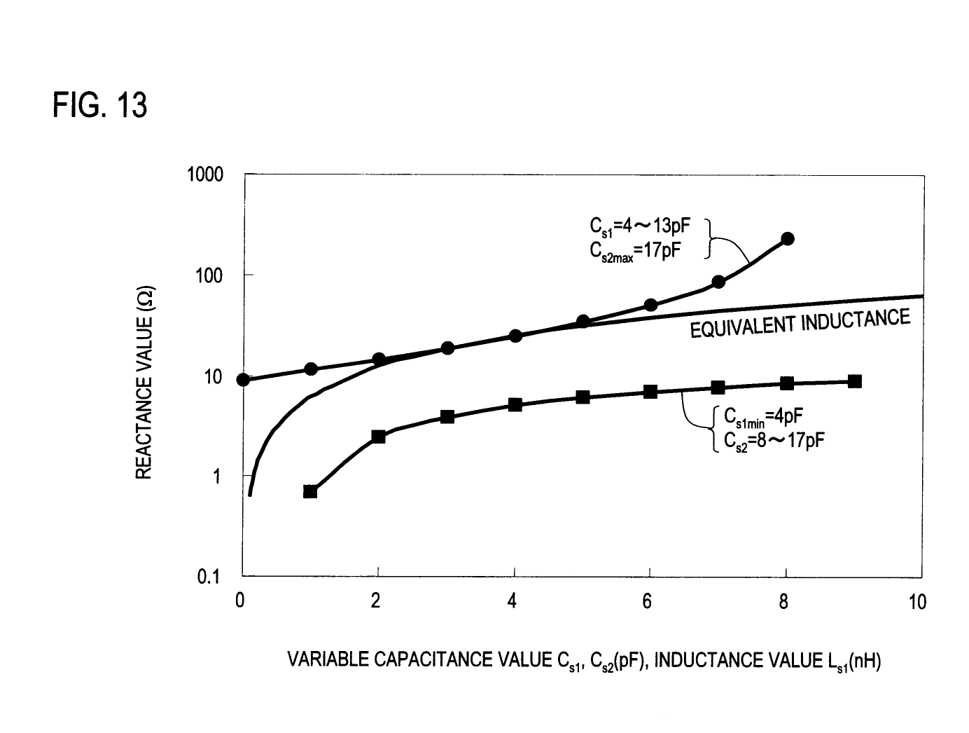

By way of illustration, required Cₛ₁ and Cₛ₂ when an input signal frequency is 1 GHz and Lₛ₁ₒ is 2 nH will be calculated. From Expression (18a), Cₛ₁ₘₐₓ is approximately 12.7 pF. For simplicity, assume that Cₛ₁ₘₐₓ is 13 pF and Δₛ₁ is 9 pF. Then 4≦Cₛ₁≦13 pF. Here, since Cₛ₁ₘᵢₙ is 4 pF, Cₛ₂ is 8.7 pF or more from Expression (18b). For simplicity, assume that Cₛ₂ₘᵢₙ is 8 pF and Δₛ₂ is 9 pF. Then 8≦Cₛ₂≦17 pF. FIG. 13 illustrates plots of reactance values in the configuration in FIG. 12 in which Cₛ₁ in FIG. 11 is divided into two, Cₛ₁′ and Cₛ₁ₒ, and Cₛ₂ in FIG. 11 is divided into two, Cₛ₂′ and Cₛ₂ₒ, where Cₛ₁ₒ=4 pF, Cₛ₂ₒ=8 pF, and variable capacitance values Cₛ₁′ and Cₛ₂′ are changed in the ranges Δₛ₁ and Δₛ₂ (0 to 9 pF), respectively (variable capacitance value versus reactance value characteristics). The filled circles represent a plot obtained by changing Cₛ₁′ while Cₛ₂ is fixed at Cₛ₂ₘₐₓ (=17 pF) and filled squares represent a plot obtained by changing Cₛ₂′ while Cₛ₁ is fixed at Cₛ₁ₘᵢₙ (=4 pF). The solid curve without circles nor squares represents a reactance value obtained by changing the inductance value equivalent to the variable inductive element Lₛ₁ in FIG. 14D in the range of 0 to 10 nH. It can be seen from FIG. 13 that reactance value adjustment in a range equivalent to a range achievable by changing the inductance value Lₛ₁ by 10 nH or more can be achieved by changing the values of Cₛ₁ and Cₛ₂, when the input signal frequency=1 GHz, Lₛ₁ₒ=2 nH, Cₛ₁=4 to 13 pF and Cₛ₂=8 to 17 pF.

The configuration in FIG. 14D has been changed to a configuration that does not use a variable inductive element in the third embodiment described above. The configuration in FIG. 14C also can be changed to a configuration that does not use a variable inductive element in a way similar to that in the third embodiment.

In this way, the variable impedance matching circuit 300 of the present invention is capable of adjusting impedance without using a variable inductive element as if the circuit 300 were using a variable inductive element. Accordingly, the variable impedance matching circuit 300 is capable of dealing with variations in load in a wide range with a small number of elements.

The allocations of functions of the components of the variable impedance matching circuits 100, 150, 200 and 300 of the present invention described above are not limited to those described in the embodiments. Changes can be made to the allocations as appropriate without departing from the scope of the present invention.

What is claimed is:

1. A variable impedance matching circuit comprising:
a series or parallel connection of a fixed inductive element and a first variable capacitive element; and
a second variable capacitive element connected in series with the series or parallel connection;
wherein susceptance of the circuit can be changed by changing the capacitance of each of the variable capacitive elements.

2. The variable impedance matching circuit according to claim 1, further comprising a series connection of a third variable capacitive element and a fourth variable capacitive element;
wherein both ends of the series connection between the series connection of the fixed inductive element and the first variable capacitive element and the second variable capacitive element are grounded; and
a connection point of the series connection of the third variable capacitive element and the fourth variable capacitive element is connected to a connection point of the series connection between the series connection of the fixed inductive element and the first variable capacitive element and the second variable capacitive element.

3. The variable impedance matching circuit according to claim 2, further comprising:
a first fixed capacitive element, one end of the first fixed capacitive element being connected to one end of the first variable capacitive element, the other end of the first fixed capacitive element being connected to the other end of the first variable capacitive element; and
a second fixed capacitive element, one end of the second fixed capacitive element being connected to one end of the second variable capacitive element, the other end of the second fixed capacitive element being connected to the other end of the second variable capacitive element.

4. The variable impedance matching circuit according to claim 3, wherein:
the capacitance value Cₚ₁ₒ of the first fixed capacitive element satisfies the expressions
$$0 < {C}_{p 1 o} \leq {C}_{p 1 min}$$
$${C}_{p 1 min} \leq \frac{1}{{ω}^{2} {L}_{p 1 o}}$$
where ω is the angular frequency of an input signal, Cₚ₁ₘᵢₙ is a minimum value of the sum of Cₚ₁ₒ and the capacitance value of the first variable capacitive element, Lₚ₁ₒ is the inductance of the fixed inductive element; and
the capacitance value Cₚ₂ₒ of the second fixed capacitive element satisfies the expressions
$$0 < {C}_{p 2 o} \leq {C}_{p 2 max} - {Δ}_{p 2}$$
$${C}_{p 2 max} \geq \frac{1}{{ω}^{2} {L}_{p 1 o}}$$
where Cₚ₂ₘₐₓ is a maximum value of the sum of Cₚ₂ₒ and the capacitance value of the second variable capacitive element and Δₚ₂ is a range of variable capacitance covered by the second variable capacitive element.

5. The variable impedance matching circuit according to claim 1, further comprising:
a series connection of a third variable capacitive element and a fourth variable capacitive element;
wherein one end of the series connection between the parallel connection of the fixed inductive element and the first variable capacitive element and the second variable capacitive element is connected to a connection point of the series connection of the third variable capacitive element and the fourth variable capacitive element, and the other end is grounded.

6. The variable impedance matching circuit according to claim 5, further comprising:
a first fixed capacitive element, one end of the first fixed capacitive element being connected to one end of the first variable capacitive element, the other end of the first fixed capacitive element being connected to the other end of the first variable capacitive element; and
a second fixed capacitive element, one end of the second fixed capacitive element being connected to one end of the second variable capacitive element, the other end of the second fixed capacitive element being connected to the other end of the second variable capacitive element.

7. The variable impedance matching circuit according to claim 6, wherein:
the capacitance value Cₚ₁ₒ of the first fixed capacitive element satisfies the expressions
$$0 < {C}_{p 1 o} \leq {C}_{p 1 max} - {Δ}_{p 1}$$
$${C}_{p 1 max} \geq \frac{1}{{ω}^{2} {L}_{p 1 o}}$$
where ω is the angular frequency of an input signal, Lₚ₁ₒ is the inductance of the fixed inductive element, Cₚ₁ₘₐₓ is a maximum value of the sum of Cₚ₁ₒ and the capacitance value of the first variable capacitive element, and Δₚ₁ is a range of variable capacitance covered by the first variable capacitive element; and
the capacitance value Cₚ₂ₒ of the second fixed capacitive element satisfies the expressions
$$0 < {C}_{p 2 o} \leq {C}_{p 2 min}$$
$${C}_{p 2 min} \leq \frac{1 - {ω}^{2} {L}_{p1 o} {C}_{p 1 min}}{{ω}^{2} {L}_{p 1 o}}$$
$${C}_{p 1 min} < \frac{1}{{ω}^{2} {L}_{p 1 o}}$$
where Cₚ₁ₘᵢₙ is a minimum value of the sum of Cₚ₁ₒ and the capacitance value of the first variable capacitive element and Cₚ₂ₘᵢₙ is a minimum value of the sum of Cₚ₂ₒ and the capacitance value of the second variable capacitive element.

8. The variable impedance matching circuit according to claim 1, further comprising a third and fourth variable capacitive elements;
wherein one end of the third variable capacitive element is connected to one end of the series connection between the parallel connection of the fixed inductive element and the first variable capacitive element and the second variable capacitive element, and the other end is grounded; and
one end of the fourth variable capacitive element is connected to the other end of the series connection between the parallel connection of the fixed inductive element and the first variable capacitive element and the second variable capacitive element, and the other end is grounded.

9. The variable impedance matching circuit according to claim 8, further comprising:
a first fixed capacitive element, one end of the first fixed capacitive element being connected to one end of the first variable capacitive element, the other end of the first fixed capacitive element being connected to the other end of the first variable capacitive element; and
a second fixed capacitive element, one end of the second fixed capacitive element being connected to one end of the second variable capacitive element, the other end of the second fixed capacitive element being connected to the other end of the second variable capacitive element.

10. The variable impedance matching circuit according to claim 9, wherein:
the capacitance value Cₛ₁ₒ of the first fixed capacitive element satisfies the expressions
$$0 < {C}_{s 1 o} \leq {C}_{s 1 max} - {Δ}_{s 1}$$
$${C}_{s 1 max} \geq \frac{1}{{ω}^{2} {L}_{s 1 o}}$$
where ω is the angular frequency of an input signal, Lₛ₁₀ is the inductance of the fixed inductive element, Cₛ₁ₘₐₓ is a maximum value of the sum of Cₛ₁ₒ and the capacitance value of the first variable capacitive element, and Δₛ₁ is a range of variable capacitance covered by the first variable capacitive element; and
the capacitance value Cₛ₂ₒ of the second fixed capacitive element satisfies the expressions
$$0 < {C}_{s 2 o} {\leq }_{s 2 min} \\ {C}_{s 2 min} \leq \frac{1 - {ω}^{2} {L}_{s 1 o} {C}_{s 1 min}}{{ω}^{2} {L}_{s 1 o}}$$
$${C}_{s 1 min} < \frac{1}{{ω}^{2} {L}_{s 1 o}}$$
where Cₛ₁ₘᵢₙ is a minimum value of the sum of Cₛ₁ₒ and the capacitance value of the first variable capacitive element and Cₛ₂ₘᵢₙ is a minimum value of the sum of Cₛ₂ₒ and the capacitance value of the second variable capacitive element.
